(19) United States
(12) Patent Application Publication
(10) Pub. No.: US 2024/0405114 A1
(43) Pub. Date: Dec. 5, 2024

(54) FIELD EFFECT TRANSISTOR AND METHOD OF MANUFACTURING THEREOF

(71) Applicant: HUAWEI TECHNOLOGIES CO., LTD., Shenzhen (CN)

(72) Inventor: Gilberto Curatola, Nuremberg (DE)

(21) Appl. No.: 18/736,138

(22) Filed: Jun. 6, 2024

Related U.S. Application Data
(63) Continuation of application No. PCT/EP2021/084366, filed on Dec. 6, 2021.

(51) Int. Cl. H01L 29/778; H01L 29/08; H01L 29/20; H01L 29/417; H01L 29/66

(52) U.S. Cl. CPC H01L 29/7783; H01L 29/0847; H01L 29/2003; H01L 29/41775; H01L 29/66462

(57) ABSTRACT

A member includes a buffer layer made of GaN. The member is characterized in that the member includes a source layer arranged on top of the buffer layer, and the source layer made of n-doped GaN. The member includes a first barrier layer made of Al—GaN arranged over the buffer layer and a first gate layer made of p-doped GaN arranged over the first barrier layer, where the first barrier layer and the first gate layer are arranged adjacent the source layer on one side. The member includes a second barrier layer made of Al—GaN arranged over the buffer layer and a second gate layer made of p-doped GaN arranged over the second barrier layer, where the second barrier layer and the second gate layer are arranged adjacent the source layer on another side. The member enables an independent optimization of the two-dimensional electron gas characteristics and the threshold voltage.

### CROSS-REFERENCE TO RELATED APPLICATIONS

This application is a continuation of International Application No. PCT/EP2021/084366, filed on Dec. 6, 2021, the disclosure of which is hereby incorporated by reference in its entirety.

### TECHNICAL FIELD

The present disclosure relates generally to the field of semiconductor devices and more specifically, to a member (e.g., a semiconductor structure), a method of manufacturing the member, and a transistor (e.g., a field effect transistor) comprising the member.

### BACKGROUND

Generally, a semiconductor device is based on electronic properties of a semiconductor material, such as silicon (Si), germanium (Ge), and the like, for its functioning. The semiconductor device is generally manufactured either as an individual device or as an integrated circuit (IC) device, using a conventional silicon-based semiconductor technology. However, the conventional silicon-based semiconductor technology has certain limits in terms of on-state resistance versus breakdown voltage. There is a super junction concept that has been extensively proven and applied to the conventional silicon-based semiconductor technology to surpass such limits. In the super junction concept, p-type doped vertical stripes are added in a drift region of the semiconductor device, which results in the formation of new PN-junctions. The super junction concept allows achieving a flat electric field distribution in the semiconductor device due to lateral depletion of an adjacent PN junction. Because of the flat electric field distribution, the super junction concept manifests a much higher doping profile and reduces a minimum achievable on-state resistance.

Currently, intensive efforts are taken to develop a possible replacement of the conventional silicon technology (or Si-based field-effect transistors (FETs)), for example, by development of wide bandgap (WBG) semiconductor materials-based technology. The wide bandgap semiconductor materials provide a partially improved performance both at a device level as well as at a system level as compared to the conventional silicon-based semiconductor technology. For example, conventional enhancement-mode gallium nitride (GaN) based power FETs (or MOSFETs) are already used by semiconductor manufacturers in various commercial products. The conventional enhancement-mode GaN based power FETs utilize a p-doped GaN normally-off concept. The p-doped GaN power transistor includes a thin aluminium gallium nitride (AlGaN) barrier layer, which is grown onto a GaN buffer layer in order to create a two-dimensional electron gas (2DEG) at the AlGaN/GaN interface. In the 2DEG, a gate module (may also be referred to as a gate metal) is composed of a p-type doped layer (e.g., magnesium is usually used as a p-type dopant), which is defined below the gate module only in the gate region. The p-doped GaN layer depletes the two-dimensional electron gas (2DEG) in the gate region and allows fabrication of the conventional enhancement-mode (normally-off) GaN power transistors. The conventional p-doped GaN power transistor, generally, includes a single AlGaN barrier layer, with a certain thickness and aluminium (Al) content, which is used to define electrical characteristics of the two-dimensional electron gas (2DEG). However, the conventional p-doped GaN power transistor has certain limitations, such as the threshold voltage and the two-dimensional electron gas (2DEG) characteristics cannot be controlled independently. Moreover, the conventional p-doped GaN power transistor is highly sensitive to surface effects (i.e., dynamic effects) and the gate module details (e.g., Schottky vs. Ohmic). Additionally, the conventional p-doped GaN power transistor manifests reduced current capabilities and low threshold voltage (e.g., approximately 1-1.5V). The reason being the conventional p-doped GaN power transistor is highly sensitive to parasitic and voltage and current overshoots. Therefore, there exists a technical problem of how to independently control the threshold voltage and the two-dimensional electron gas (2DEG) characteristics of the conventional p-doped GaN power transistor as well as to make the conventional p-doped GaN power transistor sufficiently immune to the surface effects.

Therefore, in light of the foregoing discussion, there exists a need to overcome the aforementioned drawbacks associated with the conventional p-doped GaN power transistor.

### SUMMARY

The present disclosure provides a member (e.g., a semiconductor structure), a method of manufacturing the member, and a transistor (e.g., a field effect transistor) comprising the member. The present disclosure provides a solution to the existing problem of how to independently control the threshold voltage and the two-dimensional electron gas (2DEG) characteristics of the conventional p-doped GaN power transistor as well as to make the conventional p-doped GaN power transistor sufficiently immune to the surface effects. The present disclosure provides a solution that overcomes at least partially the problems encountered in the prior art and provides an improved member (e.g., a semiconductor structure), a method of manufacturing the member, and a transistor (e.g., a field effect transistor) comprising the member with a tunable threshold voltage.

In one aspect, the present disclosure provides a member comprising a buffer layer comprising gallium nitride (GaN). The member is characterized in that the member further comprises a source layer arranged on top of the buffer layer, and the source layer comprises n-doped GaN. The member further comprises a first barrier layer comprising Al—GaN arranged over the buffer layer and a first gate layer comprising p-doped GaN arranged over the first barrier layer, where the first barrier layer and the first gate layer is arranged adjacent the source layer on one side. The member further comprises a second barrier layer comprising Al—GaN arranged over the buffer layer and a second gate layer comprising p-doped GaN arranged over the second barrier layer, where the second barrier layer and the second gate layer is arranged adjacent the source layer on another side.

The member enables an independent optimization of a two-dimensional electron gas (2DEG) characteristics and threshold voltage (Vth) of a semiconductor device (e.g., a power transistor). Moreover, the member manifests a high immunity to dynamic effects (or surface effects). The member is less sensitive to the thickness and concentration of each of the first and second barrier layers. The member allows a high 2DEG density to boost on-state resistance. However, the on-state resistance and the threshold voltage can be controlled independently.

In an implementation form, one or more drain (D) contacts are arranged on at least one of the first and second barrier layers, one or more gate (G) contacts are arranged on at least one of the first and second gate layers, and a source (S) contact is arranged on the source layer.

Each of the one or more drain (D) contacts, the one or more gate (G) contacts, and the source (S) contact is arranged for electric field management.

In a further implementation form, the source layer is arranged in a hole in the first and second barrier layers and the first and second gate layers, where the source layer is sandwiched between the first and second barrier layers and the first and second gate layers.

The source layer is arranged in the hole in the first and second barrier layers and the first and second gate layers, in order to improve the electrical properties of the member, which further results in improved electrical properties of a semiconductor device comprising the member.

In a further implementation form, the hole is formed in an original barrier layer and an original gate layer, the first and second barrier layers and the first and second gate layers and, where the source layer is a regrown body of n-doped GaN in the hole.

By virtue of using the source layer as the regrown body of n-doped GaN in the hole, on-state resistance of a semiconductor device as well as its overall breakdown capabilities are improved.

In a further implementation form, the member comprises a first portion of the member, the first portion is arranged, in operation, to have current flow through it in a vertical direction, and a second portion of the member, the second portion is arranged, in operation, to have current flow through it in a lateral direction, and where the threshold voltage of the member is dependent on the first portion.

The member manifests the advantages of a conventional GaN lateral technology as well as the benefits of a vertical device architecture due to the presence of the first portion and the second portion.

In a further implementation form, the first portion of the member comprises the source layer and a portion of the first gate layer, and where the second portion of the member comprises the remainder of the first gate layer and, the first barrier layer.

By virtue of using such arrangement of the first portion as well as the second portion, the member combines the advantages of a lateral technology with that of a pure vertical technology. Additionally, the member manifests a reduced manufacturing complexity using such arrangement of the first portion as well as the second portion.

In a further implementation form, the first portion of the member further comprises a portion of the second gate layer, and where the second portion of the member further comprises the remainder of the second gate layer and the second barrier layer.

By virtue of using such arrangement of the first portion as well as the second portion, the member combines the advantages of a lateral technology with that of a pure vertical technology. Additionally, the member manifests a reduced manufacturing complexity using such arrangement of the first portion as well as the second portion.

In a further implementation form, the source layer has a first length in a first lateral direction and a length in a second lateral direction, each of the first and second gate layers has a first length in a first lateral direction and a length in a second lateral direction, where the lengths of either gate layer are measured from the source layer, and each of the first and second barrier layers has a first length in a first lateral direction and a length in a second lateral direction, where the lengths of either barrier layer are measured from the source layer, where the first lateral direction is orthogonal to the second lateral direction.

By virtue of having the dimensions of each of the source layer, the first and second gate layers and the first and second barrier layers, in the first lateral direction and the second lateral direction, a tunable threshold voltage can be obtained.

In a further implementation form, the member further comprises one or more further first barrier layers and one or more first intermediate buffer layers arranged between the first barrier layer and the buffer layer and one or more further second barrier layers and one or more second intermediate buffer layers arranged between the second barrier layer and the buffer layer, where the further barrier layers comprise AlGaN, and where the intermediate buffer layers comprise GaN.

By virtue of using the one or more further first barrier layers and the one or more first intermediate buffer layers arranged between the first barrier layer and the buffer layer and the one or more further second barrier layers and one or more second intermediate buffer layers arranged between the second barrier layer and the buffer layer, multiple channels in parallel are created, which further enhance the electrical properties of the member.

In another aspect, the present disclosure provides a method of manufacturing a member. The method comprises depositing a sacrificial layer on top of an epitaxial stack. The epitaxial stack comprises a buffer layer comprising GaN, a barrier layer comprising Al—GaN arranged over the buffer layer, and a gate layer comprising p-doped GaN arranged over the barrier layer, where the sacrificial layer indicates location for a hole. The method further comprises etching the hole through the gate layer and the barrier layer as indicated by the sacrificial layer and regrowing a source layer comprising n-doped GaN in the hole. The method further comprises removing the sacrificial layer and structuring the gate layer exposing a portion of the barrier layer and depositing a passivation layer over the exposed portion of the barrier layer, the gate layer and the source layer. The method further comprises arranging one or more drain contacts on the barrier layer, arranging one or more gate contacts on the gate layer and arranging a source contact on the source layer.

The method achieves all the advantages and technical effects of the member of the present disclosure.

In yet another aspect, the present disclosure provides a field effect transistor (FET) having a source contact, one or more gate contacts and, one or more drain contacts. The FET comprises a junction field effect transistor (JFET) and a first and a second heterostructure FETs. The JFET is arranged to provide the source contact of the FET and, the first and the second heterostructure FETs are arranged to provide the one or more gate contacts and the one or more drain contacts of the FET.

The FET achieves all the advantages and technical effects of the member of the present disclosure.

It is to be appreciated that all the aforementioned implementation forms can be combined. It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1 is a schematic illustration of a member, in accordance with an embodiment of the present disclosure;

FIGS. 2A, 2B, and 2C collectively illustrate a schematic process for manufacturing a member in two-dimensions (2D), in accordance with an embodiment of the present disclosure;

FIG. 3A is a schematic illustration of a member, in accordance with another embodiment of the present disclosure;

FIG. 3B is a schematic illustration of a member, in accordance with yet another embodiment of the present disclosure;

FIGS. 4A and 4B collectively illustrate a schematic process for manufacturing a member in three-dimensions (3D), in accordance with an embodiment of the present disclosure;

FIG. 5 is a flowchart of a method of manufacturing a member, in accordance with an embodiment of the present disclosure;

FIG. 6 is a schematic illustration of a field effect transistor (FET), in accordance with an embodiment of the present disclosure;

FIG. 7A is a graphical representation that illustrates simulated electrical transfer characteristics of a semiconductor device, as a function of voltage applied to a gate electrode and for different values of lateral extension of gallium nitride (GaN) regrown region, in accordance with an embodiment of the present disclosure; and

FIG. 7B is a graphical representation that illustrates simulated electrical transfer characteristics of a semiconductor device, as a function of voltage applied to a gate electrode and for different values of n-type doping concentration in the gallium nitride (GaN) regrown region, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

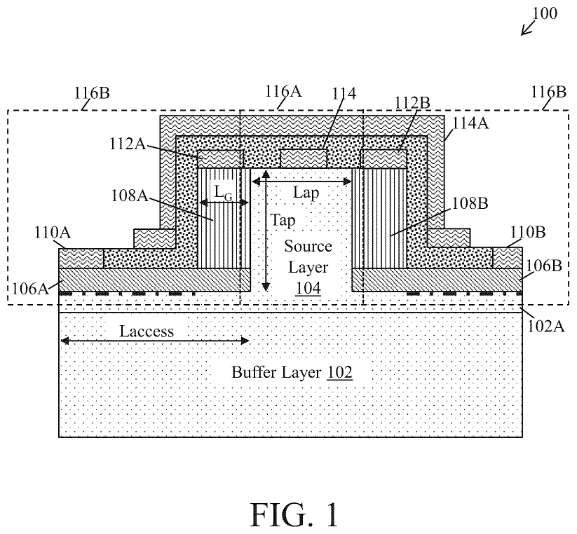

FIG. 1 is a schematic illustration of a member, in accordance with an embodiment of the present disclosure. With reference to FIG. 1, there is shown a schematic illustration of a member 100 that includes a buffer layer 102, a source layer 104, a first barrier layer 106A, a second barrier layer 106B, a first gate layer 108A, and a second gate layer 108B. The member 100 further includes one or more drain contacts, such as a first drain contact 110A and a second drain contact 110B, one or more gate contacts, such as a first gate contact 112A, and a second gate contact 112B, and a source contact 114. There is further shown a first portion 116A and a second portion 116B of the member 100. There is further shown a metal layer 114A.

The member 100 is a semiconductor structure that includes one or more layers of semiconductor material. In an example, the semiconductor material of one layer may be the same (or different) as compared to the semiconductor material of another layer. The member 100 may also comprise layers or structures of materials other than the semiconductor materials. Further, the member 100 may constitute a semiconductor device or be comprised in the semiconductor device. The member 100 corresponds to an epitaxial stack. The member 100 may be represented either as a two-dimensional structure or a three-dimensional structure.

The buffer layer 102 is a layer of gallium nitride (GaN) semiconductor material, which is a wide-bandgap (WBG) semiconductor material. The bandgap of the buffer layer 102 is of a value of 3.4 electron volt (eV). The buffer layer 102 is generally composed of a top part 102A that acts as an un-intentionally doped (UID) GaN channel and a bottom part that is generally carbon doped. The carbon doped bottom part provides a significant decrease in the lateral parasitic leakage current and also, an increase in overall breakdown voltage of a semiconductor device (both horizontally and vertically).

The source layer 104 is a layer of n-doped GaN, and arranged over the buffer layer 102.

Each of the first barrier layer 106A, and the second barrier layer 106B is a layer of aluminium gallium nitride (AlGaN) semiconductor material. Each of the first barrier layer 106A, and the second barrier layer 106B is arranged over the buffer layer 102 in order to create a two-dimensional electron gas (2DEG) at the AlGaN/GaN interface. The 2DEG is represented by a dotted line on adjacent sides of the source layer 104 in the member 100, as shown in FIG. 1. The 2DEG is a scientific model in solid-state physics, where the two-dimensional electron gas is free to move in two dimensions, but tightly confined in a third dimension. Moreover, such tight confinement leads to quantized energy levels for the motion of the two-dimensional electron gas in the third dimension, which can then be ignored for most problems. Thus, the two-dimensional electron gas appears to be a two-dimensional (2D) sheet embedded in a three-dimensional (3D) world. Each of the first barrier layer 106A, and the second barrier layer 106B may also be referred to as an access region.

Each of the first gate layer 108A, and the second gate layer 108B is a layer of p-doped GaN semiconductor material. The first gate layer 108A and the second gate layer 108B are arranged over the first barrier layer 106A, and the second barrier layer 106B, respectively. Usually, magnesium (Mg) is used as a p-type dopant to the gallium nitride (GaN) semiconductor material.

Each of the one or more drain contacts, such as the first drain contact 110A and the second drain contact 110B, the one or more gate contacts, such as the first gate contact 112A, and the second gate contact 112B, and the source contact 114 correspond to a metal drain contact, a metal gate contact, and a metal source contact terminal, respectively, of the member 100, which is used for electrical connection purposes. Generally, the metal used for each of the first drain contact 110A, the second drain contact 110B, the first gate contact 112A, and the second gate contact 112B, and the source contact 114 may be one of or a combination of palladium (Pd), titanium (Ti), titanium nitride (TiN), gold (Au), nickel (Ni), aluminium (Al), and tungsten (W).

The member 100 comprises the buffer layer 102 comprising gallium nitride (GaN). The member 100 is characterized in that the member 100 further comprises the source layer 104 arranged on top of the buffer layer 102. The source layer 104 comprises n-doped GaN. The member 100 further comprises the first barrier layer 106A comprising Al—GaN arranged over the buffer layer 102 and the first gate layer 108A comprising p-doped GaN arranged over the first barrier layer 106A, where the first barrier layer 106A and the first gate layer 108A is arranged adjacent to the source layer 104 on one side. In the member 100, the source layer 104 made of the n-doped GaN semiconductor material is arranged on top of the buffer layer 102. Additionally, the first barrier layer 106A made of the Al—GaN semiconductor material is arranged over the buffer layer 102. In an implementation of the member 100, the first barrier layer 106A may be arranged directly on top of the buffer layer 102. In another implementation of the member 100, the first barrier layer 106A may be arranged above the buffer layer 102 potentially with another material in between the first barrier layer 106A and the buffer layer 102. For example, the top part 102A (i.e., UID GaN channel) of the buffer layer 102 may be arranged in between the first barrier layer 106A and the buffer layer 102. Moreover, the first gate layer 108A made of p-doped GaN semiconductor material is arranged over the first barrier layer 106A. Each of the first barrier layer 106A and the first gate layer 108A is arranged adjacent (e.g., on left side) of the source layer 104.

The member 100 further comprises the second barrier layer 106B comprising Al—GaN arranged over the buffer layer 102 and the second gate layer 108B comprising p-doped GaN arranged over the second barrier layer 106B, where the second barrier layer 106B and the second gate layer 108B is arranged adjacent to the source layer 104 on another side. Similar to the first barrier layer 106A, the second barrier layer 106B is made of the Al—GaN semiconductor material and is arranged either directly on top of the buffer layer 102 or above the buffer layer 102 potentially with the other material (e.g., the top part 102A, UID GaN channel, of the buffer layer 102) in between the second barrier layer 106B and the buffer layer 102. Similar to the first gate layer 108A, the second gate layer 108B is made of the p-doped GaN semiconductor material and is arranged over the second barrier layer 106B. Each of the second barrier layer 106B and the second gate layer 108B is arranged adjacent (e.g., right side) to the source layer 104. Alternatively stated, each of the second barrier layer 106B and the second gate layer 108B is arranged on opposite side to the side of the source layer 104 on which each of the first barrier layer 106A and the first gate layer 108A is arranged.

In accordance with an embodiment, the one or more drain, D, contacts are arranged on at least one of the first and second barrier layers 106A, 106B. The one or more gate, G, contacts are arranged on at least one of the first and second gate layers 108A, 108B, and the source, S, contact 114 is arranged on the source layer 104. The one or more drain (may also be represented as D) contacts, such as the first drain contact 110A and the second drain contact 110B is arranged on the first barrier layer 106A and the second barrier layer 106B, respectively. Similarly, the one or more gate (may also be represented as G) contacts, such as the first gate contact 112A and the second gate contact 112B is arranged on the first gate layer 108A and the second gate layer 108B, respectively. In an implementation, each of the first drain contact 110A and the first gate contact 112A arranged on the first barrier layer 106A and the first gate layer 108A, respectively, lies on left side of the source layer 104. Additionally, each of the second drain contact 110B and the second gate contact 112B arranged on the second barrier layer 106B and the second gate layer 108B, respectively, lies on right side of the source layer 104. The source (may also be represented as S) contact 114 is arranged on the source layer 104. Furthermore, each of the one or more drain contacts, the one or more gate contacts and the source contact 114 may be either ohmic or Schottky, depending on use. Moreover, the metal layer 114A is used for electric field management. The metal layer 114A is configured to operate at a certain potential (e.g., same as that of the source contact 114) in the member 100. The metal layer 114A may also be referred to as a metal plate, which may be either ohmic or Schottky, depending on use.

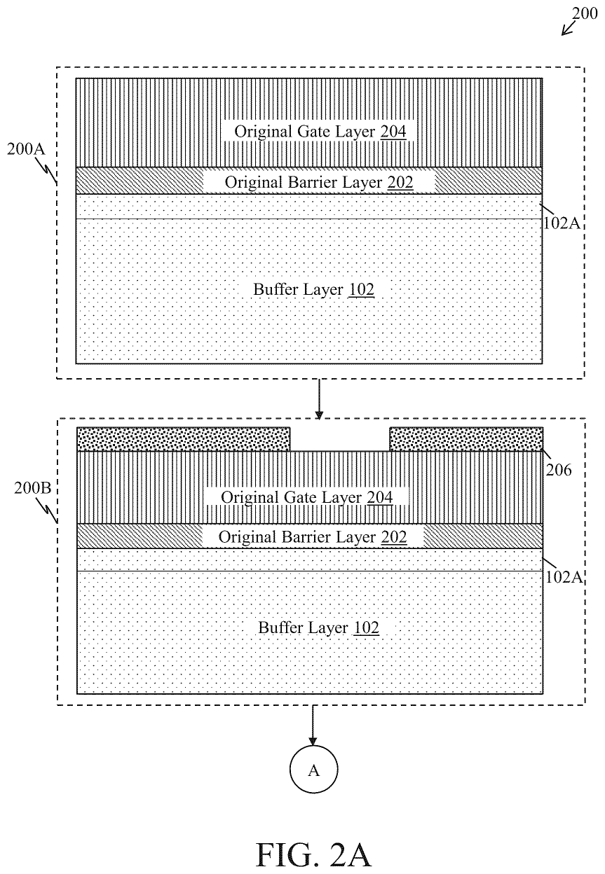

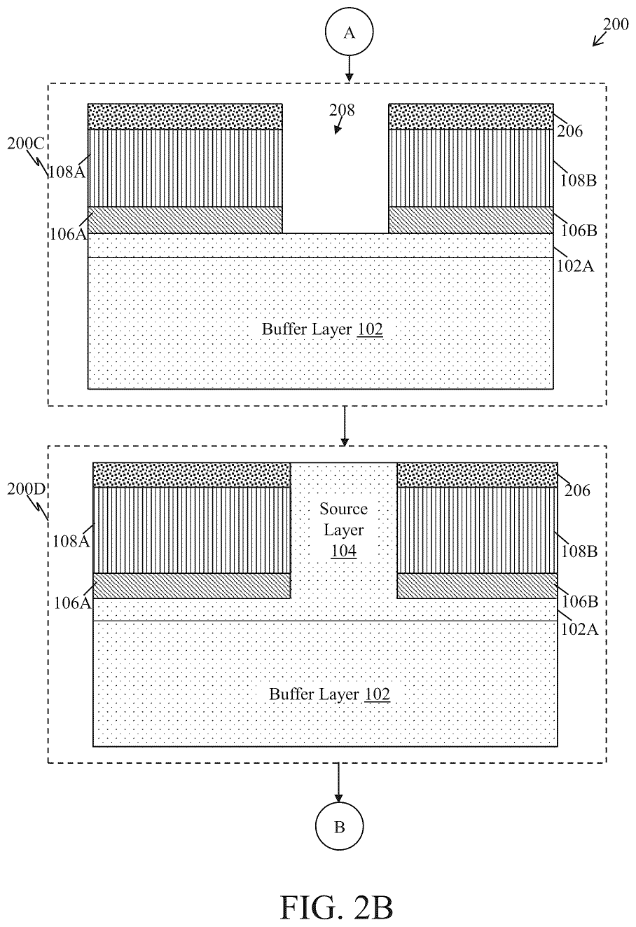

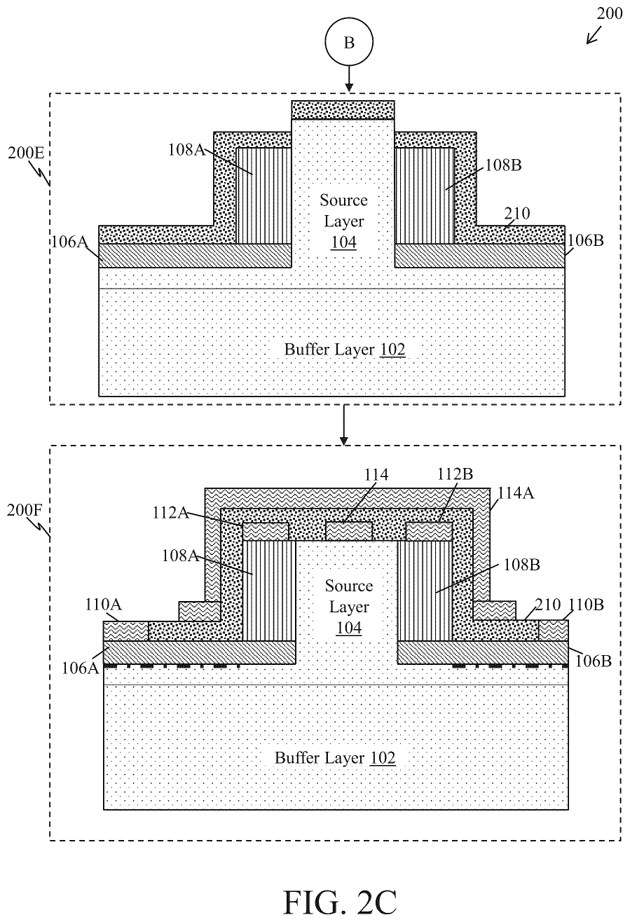

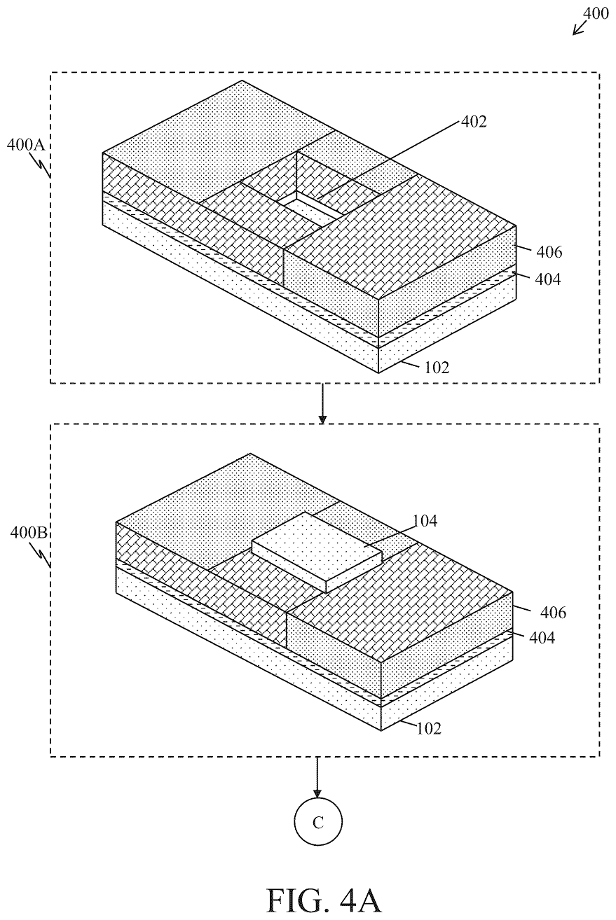

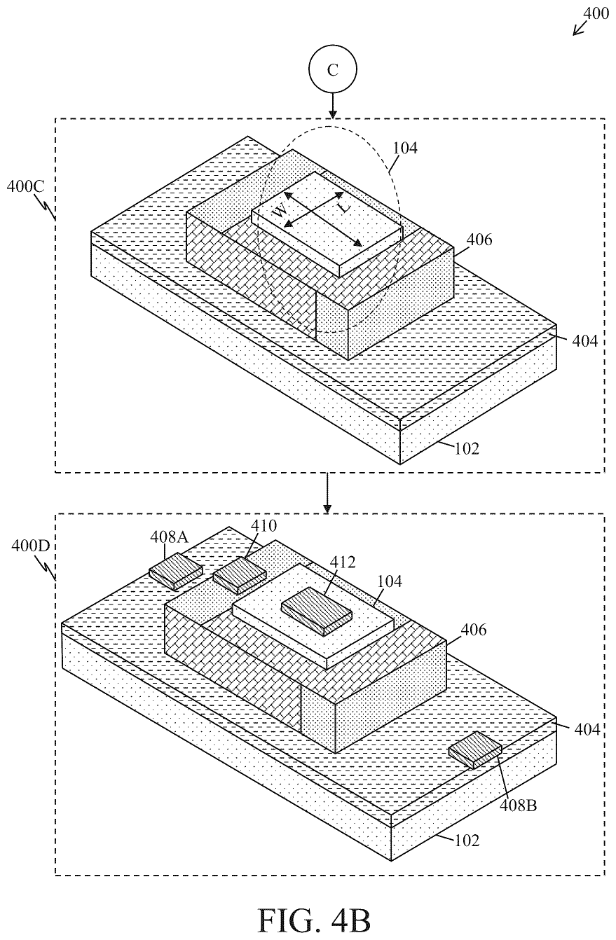

In accordance with an embodiment, the source layer 104 is arranged in a hole in the first and second barrier layers 106A, 106B and the first and second gate layers 108A, 108B, where the source layer 104 is sandwiched between the first and second barrier layers 106A, 106B and the first and second gate layers 108A, 108B. In an implementation, the source layer 104 is arranged as the hole in the first and second barrier layers 106A, 106B and the first and second gate layers 108A,108B. Alternatively stated, the source layer 104 is sandwiched between the first and second barrier layers 106A, 106B and the first and second gate layers 108A, 108B. The more details are provided in FIGS. 2B, 2C, 4A, and 4B.

In accordance with an embodiment, the member 100 comprises the first portion 116A of the member 100. The first portion 116A is arranged, in operation, to have current flow through it in a vertical direction. The member 100 further comprises the second portion 116B of the member 100. The second portion 116B is arranged, in operation, to have current flow through it in a lateral direction, and where the threshold voltage of the member 100 is dependent on the first portion 116A. The first portion 116A of the member 100 may extend from the hole in which, the source layer 104 is arranged, in a vertical direction, so that the current flows through it (i.e., the first portion 116A) in the vertical direction. Additionally, the second portion 116B of the member 100 may extend laterally to the source layer 104 including the first and second barrier layer 106A, 106B, and the first and second gate layers 108A, 108B that lie on adjacent sides (i.e., left and right) of the source layer 104. The second portion 116B is arranged laterally, so that the current flows through it (i.e., the second portion 116B) in the lateral direction. Moreover, the first portion 116A may be used in order to control the threshold voltage (Vth) of the member 100.

In accordance with an embodiment, the first portion 116A of the member 100 comprises the source layer 104 and a portion of the first gate layer 108A, and where the second portion 116B of the member 100 comprises the remainder of the first gate layer 108A layer and the first barrier layer 106A. For example, the first portion 116A of the member 100 includes the portion of the first gate layer 108A that lies on adjacent side (e.g., left side) of the source layer 104. And, the second portion 116B of the member 100 includes the remainder of the first gate layer 108A and the first barrier layer 106A that lies on the adjacent side (e.g., left side) of the source layer 104.

In accordance with an embodiment, the first portion 116A of the member 100 further comprises a portion of the second gate layer 108B, and where the second portion 116B of the member 100 further comprises the remainder of the second gate layer 108B and the second barrier layer 106B. For example, the first portion 116A of the member 100 further includes the portion of the second gate layer 108b that lies on adjacent side (e.g., right side) of the source layer 104. And, the second portion 116B of the member 100 includes the remainder of the second gate layer 108B and the second barrier layer 106B that lies on the adjacent side (e.g., right side) of the source layer 104.

In accordance with an embodiment, the source layer 104 has a first length in a first lateral direction and a length in a second lateral direction, each of the first and second gate layers 108A, 108B has a first length in a first lateral direction and a length in a second lateral direction, where the lengths of either gate layer are measured from the source layer 104, and each of the first and second barrier layers 106A, 106B has a first length in a first lateral direction and a length in a second lateral direction, where the lengths of either barrier layer are measured from the source layer 104, where the first lateral direction is orthogonal to the second lateral direction. The source layer 104 of the member 100 has the first length (e.g., lateral aperture, Lap) in the first lateral direction and the length in the second lateral direction. The first lateral direction is orthogonal to the second lateral direction. Therefore, it may be stated that the first lateral direction and the second lateral direction corresponds to width (W) and length (L) of the source layer 104. Similar to the source layer 104, each of the first gate layer 108A and the second gate layer 108B has the first length (e.g., a gate length, L_{G}) in the first lateral direction and the length in the second lateral direction. Similarly, each of the first barrier layer 106A and the second barrier layer 106B has the first length (may also be termed as lateral extension of access regions, L_{access}) in the first lateral direction and the length in the second lateral direction. Moreover, the lengths of each of the first and second gate layers 108A, 108B and each of the first and second barrier layers 106A, 106B is measured from the source layer 104.

In accordance with an embodiment, the first length of the source layer 104 in the first lateral direction is in a range of 0.2 μm to 5 μm. The first length (i.e., Lap) of the source layer 104 in the first lateral direction is in a range of 0.2 μm to 5 μm.

In accordance with an embodiment, the length of the source layer 104 in the second lateral direction is in a range of 0.2 μm to 5 μm. The length of the source layer 104 in the second lateral direction may have values in a range of 0.2 μm to 5 μm.

In accordance with an embodiment, the first length of either gate layer in the first lateral direction is in a range of 0.2 μm to 5 μm. In an implementation, the first length (i.e., gate length, L_{G}) of each of the first gate layer 108A and the second gate layer 108B in the first lateral direction, that is measured from the source layer 104 in adjacent direction (i.e., left and right direction of the source layer 104), may be of same value that lies in the range of 0.2 μm up to 5 μm. In another implementation, the first length (i.e., gate length, L_{G}) of each of the first gate layer 108A and the second gate layer 108B in the first lateral direction, that is measured from the source layer 104 in adjacent direction (i.e., left and right direction of the source layer 104), may be of different value that lies in the range of 0.2 μm up to 5 μm. Alternatively stated, each of the first and second gate layers 108A, 108B may have either same gate lengths or different gate lengths in the first lateral direction.

In accordance with an embodiment, at least one of the gate layers has a second length in the first lateral direction measured from the source layer 104, where the second length in the first lateral direction is in a range of 0.2 μm to 5 μm. In an implementation, at least one of the first and second gate layers 108A, 108B has the second length in the first lateral direction in the range of 0.2 μm to 5 μm. Similar to the first length, the second length is also measured from the source layer 104. Moreover, the first length as well as the second length of each of the first and second gate layers 108A, 108B in the first lateral direction allows the member 100 to have the first portion 116A and the second portion 116B.

In accordance with an embodiment, the length of either gate layer in the second lateral direction is in a range of 0.2 μm to 5 μm. The length of either one of the first and second gate layers 108A, 108B or both the first and second gate layers 108A, 108B in the second lateral direction lies in a range of 0.2 μm to 5 μm.

In accordance with an embodiment, the first length of either barrier layer in the first lateral direction is in a range of 1 μm to 20 μm. In an implementation, the first length (i.e., lateral extension of access regions, L_{access}) of each of the first barrier layer 106A and the second barrier layer 106B in the first lateral direction, that is measured from the source layer 104 in adjacent direction (i.e., left and right direction of the source layer 104), may be of same value that lies in a range of 1 μm to 20 μm. In another implementation, the first length (i.e., lateral extension of access regions, L_{access}) of each of the first barrier layer 106A and the second barrier layer 106B in the first lateral direction, that is measured from the source layer 104 in adjacent direction (i.e., left and right direction of the source layer 104), may be of different value that lies in a range of 1 μm to 20 μm. Alternatively stated, each of the first and second barrier layers 106A, 106B may have either same or different lengths of access regions in the first lateral direction.

In accordance with an embodiment, at least one of the barrier layers has a second length in the first lateral direction measured from the source layer 104, where the second length in the first lateral direction is in a range of 1 μm to 20 μm. In an implementation, at least one of the first and second barrier layers 106A, 106B has the second length in the first lateral direction in the range of 1 μm to 20 μm. Similar to the first length, the second length is also measured from the source layer 104. Moreover, the first length as well as the second length of each of the first and second barrier layers 106A, 106B in the first lateral direction allows the member 100 to have the first portion 116A and the second portion 116B.

In accordance with an embodiment, the length of either barrier layer in the second lateral direction is in a range of 1 μm to 20 μm. The length of either one of the first and second barrier layers 106A, 106B or both the first and second barrier layers 106A, 106B in the second lateral direction lies in the range of 1 μm to 20 μm.

In accordance with an embodiment, a concentration of the source layer 104 is in range of 1e16 cm⁻³ up to 5e18 cm⁻³. In an implementation, Silicon (Si) may be used for n-type doping of gallium nitride (GaN) in the source layer 104 and the concentration of n-type doping lies in the range of 1e16 cm⁻³ up to 5e18 cm⁻³.

In accordance with an embodiment, a concentration of the gate layers is in a range of 1e18 cm⁻³ up to 5e19 cm⁻³. Generally, magnesium (Mg) is used for p-type doping of gallium nitride (GaN) in each of the first and second gate layers 108A, 108B and the concentration of p-type doping lies in the range of 1e18 cm⁻³ up to 5e19 cm⁻³.

In accordance with an embodiment, a concentration of aluminium in the barrier layers is in a range of 15% to 30%. The concentration of aluminium (Al) in Al—GaN of each of the first and second barrier layers 106A, 106B lies in the range of 15% to 30%. Moreover, the thickness of each of the first and second barrier layers 106A, 106B may lie in a range of 10 nm to 30 nm.

The member 100 enables an independent optimization of the two-dimensional electron gas (2DEG) characteristics and the threshold voltage (Vth) of a semiconductor device (e.g., a power transistor). Moreover, the member 100 manifests a high immunity to dynamic effects (or surface effects). The member 100 is less sensitive to the thickness and concentration (i.e., mole fraction) of each of the first and second barrier layers 106A, 106B. The member 100 allows a high 2DEG density to boost on-state resistance. However, the on-state resistance and the threshold voltage can be controlled independently. Furthermore, the n-type doping of the source layer 104 affects both the on-state resistance of the semiconductor device as well as its overall breakdown capabilities. Additionally, the member 100 manifests the advantages of a conventional GaN lateral technology as well as the benefits of a vertical device architecture due to the presence of the first portion 116A and the second portion 116B.

FIGS. 2A, 2B, and 2C collectively illustrate a schematic process for manufacturing a member in two-dimensions (2D), in accordance with an embodiment of the present disclosure. FIGS. 2A, 2B, and 2C are described in conjunction with elements from FIG. 1. With reference to FIGS. 2A, 2B and 2C, there is shown a schematic process 200 for manufacturing the member 100 (of FIG. 1) in two-dimensions (2D). The schematic process 200 includes steps 200A-to-200F. The steps 200A and 200B are shown in FIG. 2A. Similarly, the steps 200C and 200D are shown in FIG. 2B, and the steps 200E and 200F are shown in FIG. 2C.

With reference to FIG. 2A, the schematic process 200 starts with an epitaxial stack. Thereafter, at step 200A, an original barrier layer 202 is arranged over the buffer layer 102. The original barrier layer 202 is made of Aluminium Gallium nitride (AlGaN) semiconductor material. The original barrier layer 202 may be arranged either directly on top of the buffer layer 102 or potentially with another material in between the original barrier layer 202 and the buffer layer 102. For example, the top part 102A (i.e., UID GaN channel) of the buffer layer 102 may be arranged in between the original barrier layer 202 and the buffer layer 102. A typical thickness of the top part 102A (i.e., UID GaN channel) of the buffer layer 102 may lie in a range of 50 nanometers (nm) to 1 micrometer (μm).

Thereafter, an original gate layer 204 is arranged over the original barrier layer 202. The original gate layer 204 is made of p-type doped GaN semiconductor material.

At step 200B, a sacrificial passivation layer 206 is deposited over the original gate layer 204. The sacrificial passivation layer 206 may also be referred to as a “hard mask”. The sacrificial passivation layer 206 is configured to prevent oxidation of the original gate layer 204 (i.e., p-type doped gallium nitride, pGaN layer). Examples of the sacrificial passivation layer 206 include, but are not limited to, an aluminium oxide layer, aluminium nitride layer, silicon dioxide layer, the silicon nitride layer, and the like. The sacrificial passivation layer 206 is used as a masking layer for subsequent trench etching process. The sacrificial passivation layer 206 may also be referred to as a sacrificial surface passivation layer. The thickness and material composition (i.e., dielectric constant) of the sacrificial passivation layer 206 may be varied to improve the electrical characteristics of a semiconductor device (e.g., a power transistor). After deposition of the sacrificial passivation layer 206 over the original gate layer 204, a certain portion (e.g., a center portion) of the sacrificial passivation layer 206 is removed.

Now referring to FIG. 2B, at step 200C, a hole 208 (or a trench) is formed from where, the certain portion of the sacrificial passivation layer 206 is removed. The hole 208 is extended through the original gate layer 204 and the original barrier layer 202. The hole 208 is formed through subsequent etching of the sacrificial passivation layer 206, the original gate layer 204 and the original barrier layer 202. The hole 208 may also be referred to as a trench, or an opening. In an example, the hole 208 may be formed via lithography etching, photolithography, or e-beam lithography. After formation of the hole 208, the original barrier layer 202 is splitted into the first and second barrier layers 106A, 106B and the original gate layer 204 is splitted into the first and second gate layers 108A, 108B (of FIG. 1) lying on adjacent sides (e.g., left and right sides) of the hole 208.

At step 200D, the source layer 104 (of FIG. 1) is arranged in the hole 208 along with the sacrificial passivation layer 206 still in place.

In accordance with an embodiment, the hole 208 is formed in the original barrier layer 202 and the original gate layer 204, the first and second barrier layers 106A, 106B and the first and second gate layers 108A, 108B, and where the source layer 104 is a regrown body of n-doped GaN in the hole 208. The source layer 104 arranged in the hole 208 is made of n-doped GaN semiconductor material. The n-type doping in the source layer 104 improves the on-state resistance as well as threshold voltage of a semiconductor device (e.g., a power transistor) comprising the member 100.

Now referring to FIG. 2C, at step 200E, the sacrificial passivation layer 206 is removed. Also, each of the first gate layer 108A and the second gate layer 108B is structured through etching. The remaining portion of the first and second gate layers 108A, 108B define the lateral extension of the gate regions, placed at left and right sides of the source layer 104 (i.e., n-doped GaN regrown region), respectively. Thereafter, a final surface passivation layer 210 is deposited on top surface including top surface of the first and second barrier layers 106A, 106B, top surface of the first and second gate layers 108A, 108B and top surface of the source layer 104.

At step 200F, various metal contacts and the metal layer 114A is formed for electric field management. The various metal contacts include the one or more drain (i.e., D) contacts, such as the first drain contact 110A and the second drain contact 110B, the one or more gate (i.e., G) contacts, such as the first gate contact 112A and the second gate contact 112B and the source contact 114 is formed for electric field management. There is further shown the metal layer 114A, which is also used for electric field management. The metal layer 114A allows to lower down the maximum electric field in a specific portion of a semiconductor device (e.g., a power transistor) and hence, improves the overall reliability of the semiconductor device.

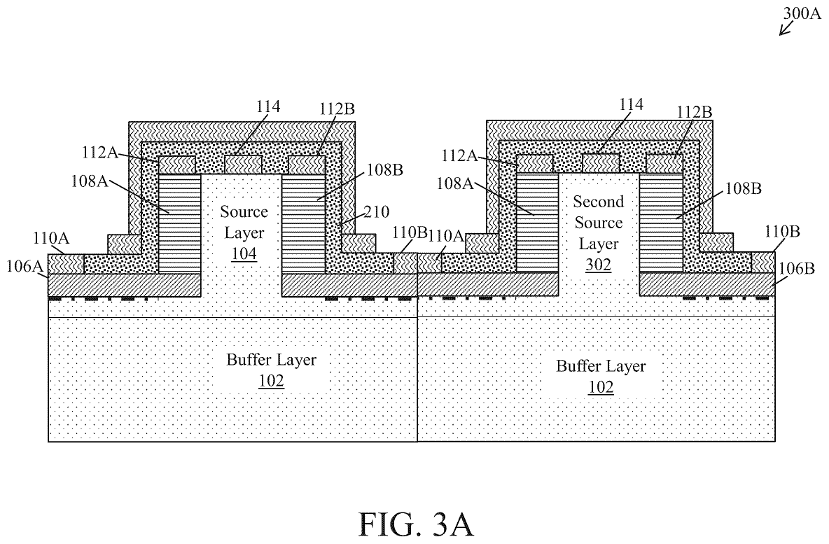

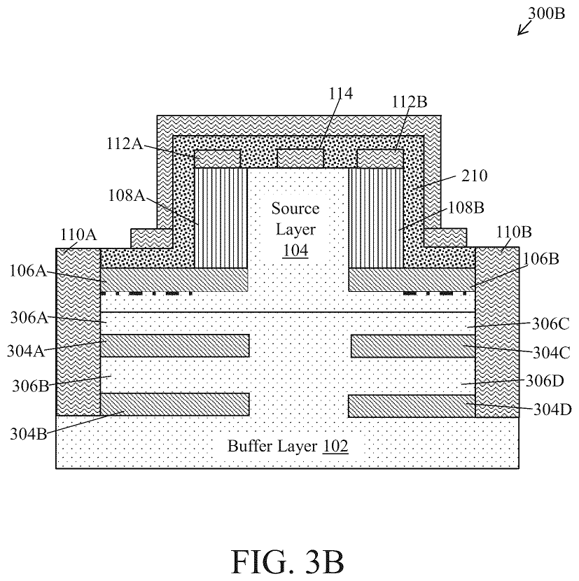

FIG. 3A is a schematic illustration of a member, in accordance with another embodiment of the present disclosure. FIG. 3A is described in conjunction with elements from FIGS. 1, 2A, 2B, and 2C. With reference to FIG. 3A, there is shown a schematic illustration of a member 300A.

The functioning of the member 300A is similar to the member 100 (of FIG. 1) except that the member 300A includes a second source layer 302.

In accordance with an embodiment, the member 300A further comprises the second source layer 302. Similar to the source layer 104, the second source layer 302 is sandwiched between the first and second barrier layers 106A, 106B and the first and second gate layers 108A, 108B.

FIG. 3B is a schematic illustration of a member, in accordance with yet another embodiment of the present disclosure. FIG. 3B is described in conjunction with elements from FIGS. 1, 2A, 2B, and 2C. With reference to FIG. 3B, there is shown a schematic illustration of a member 300B that includes one or more further first barrier layers 304A, 304B and one or more first intermediate buffer layers 306A, 306B. The member 300B further includes one or more further second barrier layers 304C, 304D and one or more second intermediate buffer layers 306C, 306D.

In accordance with an embodiment, the member 300B further comprises one or more further first barrier layers 304A, 304B and one or more first intermediate buffer layers 306A, 306B arranged between the first barrier layer 106A and the buffer layer 102 and one or more further second barrier layers 304C, 304D and one or more second intermediate buffer layers 306C, 306D arranged between the second barrier layer 106B and the buffer layer 102, where the further barrier layers comprises AlGaN, and where the intermediate buffer layers comprises GaN. In addition to the first barrier layer 106A, the member 300B further includes one or more first barrier layers 304, 304B and the one or more first intermediate buffer layers 306A, 306B. The one or more further first barrier layers 304, 304B and the one or more first intermediate buffer layers 306A, 306B are arranged in between the buffer layer 102 and the first barrier layer 106A lying on adjacent side (e.g., left side) of the source layer 104. Additionally, the member 300B includes the one or more further second barrier layers 304C, 304D and the one or more second intermediate buffer layers 306C, 306D arranged between the second barrier layer 106B and the buffer layer 102. The one or more further first barrier layers 304, 304B, the one or more first intermediate buffer layers 306A, 306B, the one or more further second barrier layers 304C, 304D, and the one or more second intermediate buffer layers 306C, 306D enables the member 300B to have multiple channels in parallel for improved electrical properties. Each of the one or more further first barrier layers 304, 304B, and the one or more further second barrier layers 304C, 304D is made of AlGaN semiconductor material. Each of the one or more first intermediate buffer layers 306A, 306B, and the one or more second intermediate buffer layers 306C, 306D is made of GaN semiconductor material.

FIGS. 4A and 4B collectively illustrate a schematic process for manufacturing a member in three-dimensions (3D), in accordance with an embodiment of the present disclosure. FIGS. 4A and 4B are described in conjunction with elements from FIGS. 1, 2A, 2B, and 2C. With reference to FIGS. 4A and 4B, there is shown a schematic process 400 for manufacturing the member 100 (of FIG. 1) in three-dimensions (3D). The schematic process 400 includes steps 400A-to-400D. The steps 400A and 400B are shown in FIG. 4A. Similarly, the steps 400C and 400D are shown in FIG. 4B.

With reference to FIG. 4A, at step 400A, a trench 402 is formed through etching. The trench 402 is surrounded from all the sides by a barrier layer 404 (i.e., AlGaN layer) and a gate layer 406 (i.e., p-GaN layer). The barrier layer 404 used in three-dimensional structure of the member 100 is nothing but the first and second barrier layers 106A, 106B as shown in two-dimensional representation of the member 100, in FIG. 1. Similarly, the gate layer 406 is represented by the first and second gate layers 108A, 108B in two-dimensional representation of the member 100, in FIG. 1. At step 400B, the source layer 104 (of FIG. 1) made of the n-type doped gallium nitride (n-GaN) semiconductor material is arranged (or regrown) in the trench 402. Alternatively stated, in practice, the source layer 104 is surrounded from all the sides by the barrier layer 404 and the gate layer 406.

Now, referring to FIG. 4B, at step 400C, the gate layer 406 (i.e., p-type doped GaN layer) is structured through etching. The source layer 104 has the first length in the first lateral direction and the length in the second lateral direction. The first lateral direction is orthogonal to the second lateral direction. Therefore, it may be stated that the first lateral direction and the second lateral direction corresponds to width (W) and length (L) of the source layer 104.

In accordance with an embodiment, a height of the source layer 104 is in a range of 0.1 μm to 5 μm. The source layer 104 (i.e., n-doped GaN regrown region) may be extended above (or below) the gate layer 406. Therefore, the source layer 104 may have the height (e.g., a vertical trench, Tap) in the range of 0.1p m to 5 μm.

In accordance with an embodiment, a height of the gate is in a range of 0.1 μm to 5 μm. The gate layer 406 has the height in the range of 0.1p m to 5 μm.

At step 400D, various metal contacts are formed for electric field management. The various metal contacts include one or more drain (i.e., D) contacts 408A, 408B formed over the barrier layer 404, one or more gate (i.e., G) contacts, such as a gate contact 410 formed over the gate layer 406 and a source contact 412 formed over the source layer 104. Each of the various metal contacts, that is the one or more drain (i.e., D) contacts 408A, 408B, the gate contact 410 and the source contact 412 surrounds the source layer 104 from all sides. The one or more drain (i.e., D) contacts 408A, 408B used in three-dimensional structure of the member 100 is nothing but the first and second drain contacts 110A, 110B as shown in two-dimensional representation of the member 100, in FIG. 1. Similarly, the gate contact 410, and the source contact 412 is represented by one of the first and second gate contacts 112A, 112B, and the source contact 114, respectively, as shown in two-dimensional representation of the member 100, in FIG. 1.

The schematic process 400 for manufacturing the member 100 (of FIG. 1) in three-dimensions (3D) allows to produce a series of the member 100 (or GaN fins) that can be connected in parallel by sharing the same source, drain and gate contacts. The schematic process 400 allows the member 100 to have an additional degree of freedom in tailoring the threshold voltage as well as electrical characteristics of a semiconductor device (e.g., a power transistor).

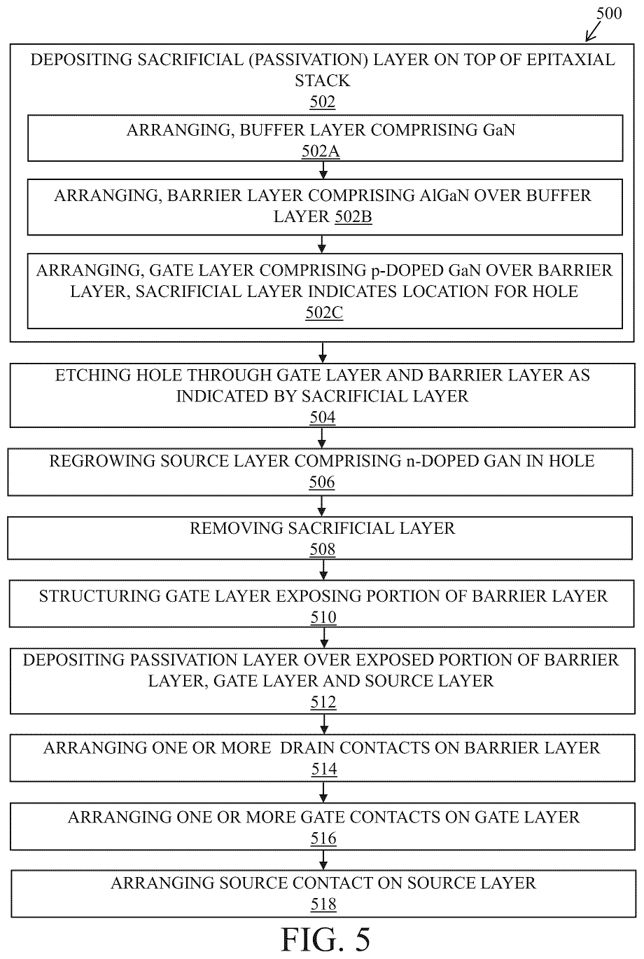

FIG. 5 illustrates a method of manufacturing a member, in accordance with an embodiment of the present disclosure. FIG. 5 is described in conjunction with elements from FIGS. 1, 2A, 2B, 2C, 4A, and 4B. With reference to FIG. 5, there is shown a method 500 for manufacturing the member 100 (of FIG. 1). The method 500 includes steps 502-to-518. The step 502 includes 502A, 502B and 502C sub-steps. The method 500 is executed by the member 100.

The present disclosure provides the method 500 of manufacturing the member 100 in two-dimensions as well as in three-dimensions.

At step 502, the method 500 comprises depositing a sacrificial (passivation) layer on top of an epitaxial stack. The sacrificial layer (i.e., the sacrificial passivation layer 206) may be configured to prevent oxidation of top surface of the epitaxial stack.

At sub-step 502A, the epitaxial stack comprises arranging the buffer layer 102 comprising GaN. The epitaxial stack starts with arranging the buffer layer 102 that is made of gallium nitride (GaN) semiconductor material.

At sub-step 502B, the epitaxial stack further comprises arranging a barrier layer comprising Al—GaN arranged over the buffer layer 102. In the epitaxial stack, the barrier layer (i.e., the original barrier layer 202, of FIG. 2A) is arranged over the buffer layer 102. The barrier layer (i.e., the original barrier layer 202) is made of aluminium gallium nitride (Al—GaN) semiconductor material.

At sub-step 502C, the epitaxial stack further comprises arranging a gate layer comprising p-doped GaN arranged over the barrier layer, where the sacrificial layer indicates location for a hole 208 (or trench). Furthermore, in the epitaxial stack, the gate layer (i.e., the original gate layer 204, of FIG. 2A) is arranged over the barrier layer (i.e., the original barrier layer 202). The gate layer (i.e., the original gate layer 204) is made of p-type doped gallium nitride (p-GaN) semiconductor material. Thereafter, the hole 208 (or the trench) is made by removing a certain portion of the sacrificial layer (i.e., the sacrificial passivation layer 206).

At step 504, the method 500 further comprises etching the hole 208 through the gate layer and the barrier layer as indicated by the sacrificial layer. The hole 208 is formed through subsequent etching of the sacrificial layer (i.e., the sacrificial passivation layer 206), the gate layer (i.e., the original gate layer 204) and the barrier layer (i.e., the original barrier layer 202).

At step 506, the method 500 further comprises regrowing the source layer 104 comprising n-doped GaN in the hole 208. Thereafter, the source layer 104 is regrown in the hole 208. The source layer 104 is made of n-doped gallium nitride (n-GaN) semiconductor material.

At step 508, the method 500 further comprises removing the sacrificial layer. After regrowing the source layer 104, the sacrificial layer (i.e., the sacrificial passivation layer 206) is removed.

At step 510, the method 500 further comprises structuring the gate layer exposing a portion of the barrier layer. Each of the gate layers (i.e., the first and second gate layers 108A, 108B) is structured by exposing the portion of each of the barrier layers (i.e., the first and second barrier layers 106A, 106B).

At step 512, the method 500 further comprises depositing a passivation layer over the exposed portion of the barrier layer, the gate layer and the source layer 104. Thereafter, the passivation layer (i.e., the final surface passivation layer 210, of FIG. 2C) is deposited over the exposed portion of each of the first and second barrier layers 106A, 106B, the first and second gate layers 108A, 108B and the source layer 104.

At step 514, the method 500 further comprises arranging one or more drain contacts 110A, 110B on the barrier layer. The one or more drain (i.e., D) contacts, such as the first drain contact 110A and the second drain contact 110B are arranged on the first and second barrier layers 106A, 106B, respectively, for electric field management.

At step 516, the method 500 further comprises arranging one or more gate contacts 112A, 112B on the gate layer. The one or more gate (i.e., G) contacts, such as the first gate contact 112A and the second gate contact 112B are arranged on the first and second gate layers 108A, 108B, respectively, for electric field management.

At step 518, the method 500 further comprises arranging the source contact 114 on the source layer 104. The source contact 114 is arranged on the source layer 104, respectively, for electric field management.

In accordance with an embodiment, the member may be any one of the members 100 (of FIG. 1) or 300A (of FIG. 3A), or 300B (of FIG. 3B), that may have either two-dimensional (2D) or three-dimensional (3D) structure.

Thus, the method 500 enables the manufacturing of the member 100 that provides an independent optimization of the two-dimensional electron gas (2DEG) characteristics and the threshold voltage (Vth) of a semiconductor device (e.g., a power transistor). Moreover, the member 100 manifests a high immunity to dynamic effects (or surface effects). Furthermore, the n-type doping of the source layer 104 affects both the on-state resistance of the semiconductor device as well as its overall breakdown capabilities. Additionally, the member 100 manifests the advantages of a conventional GaN lateral technology as well as the benefits of a vertical device architecture due to the presence of the first portion 116A and the second portion 116B.

The steps 502-to-518 are only illustrative and other alternatives can also be provided where one or more steps are added, one or more steps are removed, or one or more steps are provided in a different sequence without departing from the scope of the claims herein.

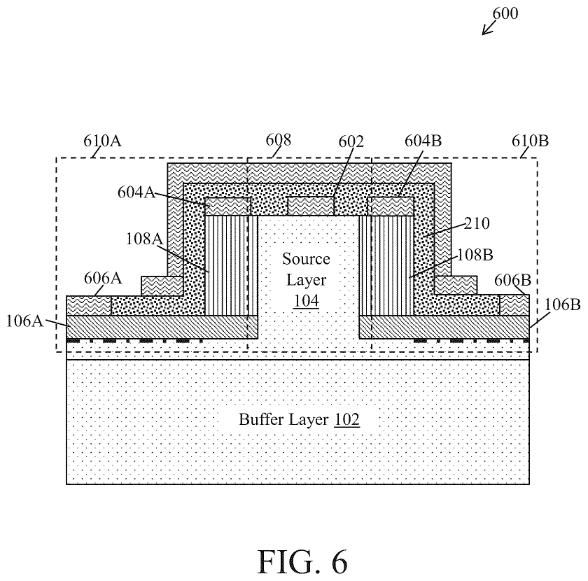

FIG. 6 is a schematic illustration of a field effect transistor (FET), in accordance with an embodiment of the present disclosure. FIG. 6 is described in conjunction with elements from FIGS. 1, 2A, 2B, 2C, 4A, and 4B. With reference to FIG. 6, there is shown a field effect transistor (FET) 600 that includes a source contact 602, one or more gate contacts, such as a first gate contact 604A and a second gate contact 604B, and one or more drain contacts, such as a first drain contact 606A and a second drain contact 606B. The FET 600 further includes a junction field effect transistor (JFET) 608 and a first and second heterostructure FETs 610A, 610B.

The FET 600 is a gallium nitride (GaN) semiconductor device (e.g., power transistor) which comprises the advantage of a conventional GaN lateral technology and the benefits of a vertical GaN semiconductor architecture (e.g., the member 100). In an implementation, the FET 600 may be a metal oxide semiconductor (MOS) FET.

The JFET 608 is arranged to provide the source contact (S) 602 of the FET 600 and where the first and second heterostructure FETs 610A, 610B are arranged to provide the one or more gate contacts 604A, 604B and the one or more drain contacts 606A, 606B of the FET 600. The first and second heterostructure FETs 610A, 610B may also be referred to as p-GaN high electron mobility transistors (HEMT).

In accordance with an embodiment, the first and second heterostructure FETs 610A, 610B are arranged to provide each a gate and a drain of the one or more gate contacts 604A, 604B and the one or more drain contacts 606A, 606B of the FET 600. For example, the first heterostructure FET 610A is arranged to provide the first gate contact 604A and the first drain contact 606A on adjacent side (e.g., left side) of the JFET 608. Similarly, the second heterostructure FET 610B is arranged to provide the second gate contact 604B and the second drain contact 606B on adjacent side (e.g., right side) of the JFET 608.

In accordance with an embodiment, the first and second heterostructure FETs 610A, 610B are p-GaN heterostructure FETs.

In accordance with an embodiment, the first and second heterostructure FETs 610A, 610B are formed as one structure enveloping the JFET 608. Alternatively stated, the JFET 608 is sandwiched between the first and second heterostructure FETs 610A, 610B.

In accordance with an embodiment, the FET 600 provides for a threshold voltage in the range of 2 to 6 V. The FET 600 provides the threshold voltage in the range of approximately 2V to more than 6V.

In accordance with an embodiment, the FET 600 comprises the member 100, 300A, 300B. The FET 600 may comprise any one of the members 100, 300A, 300B.

The FET 600 is a semi-vertical semiconductor device due to the presence of the JFET 608 and the first and second heterostructure FETs 610A, 610B. Since the FET 600 is the semi-vertical semiconductor device, a very high integration density can be obtained. The FET 600 allows a tunable threshold voltage, which can be controlled using different parameters, such as by controlling the doping and dimensions (e.g., length and depth) of the JFET 608 and by controlling the doping and dimensions of each of the first and second barrier layers 106A, 106B. Due to the presence of two channels in parallel, the FET 600 drives a much higher current than a conventional pGaN semiconductor device. Moreover, the FET 600 manifests a high immunity to dynamic effects (or surface effects). Additionally, the FET 600 manifests an independent optimization of the two-dimensional electron gas (2DEG) characteristics and the threshold voltage.

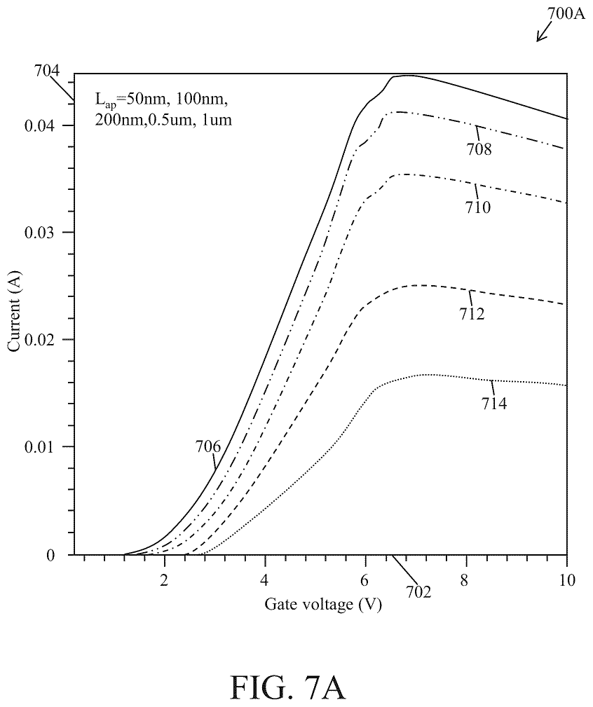

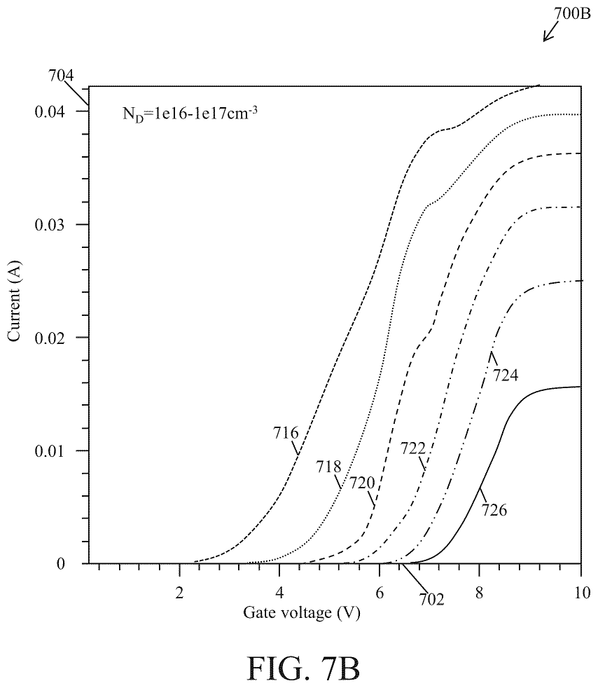

FIG. 7A is a graphical representation that illustrates simulated electrical transfer characteristics of a semiconductor device, as a function of voltage applied to a gate electrode and for different values of lateral extension of gallium nitride (GaN) regrown region, in accordance with an embodiment of the present disclosure. FIG. 7A is described in conjunction with elements from FIGS. 1, 2A, 2B, 2C, 3A, 3B, 4A, 4B, and 6. With reference to FIG. 7A, there is shown a graphical representation 700A that includes a X-axis 702 that illustrates gate voltage and a Y-axis 704 that illustrates current in amperes (A).

With reference to the graphical representation 700A, a first line 706, a second line 708, a third line 710, a fourth line 712 and a fifth line 714, collectively illustrate the simulated electrical transfer characteristics of a semiconductor device (e.g., the FET 600), as a function of voltage applied to a gate electrode and for different values of lateral extension of gallium nitride (GaN) regrown region (i.e., the source layer 104). The different values of lateral extension of gallium nitride (GaN) regrown region (i.e., the source layer 104) may be of 50 nm, 100 nm, 200 nm, 0.5 μm, and 1 μm. The additional device parameter (i.e., source layer 104) allows a fine tuning of the semiconductor device's (i.e., the FET 600) threshold voltage as well as of the saturation current.

FIG. 7B is a graphical representation that illustrates simulated electrical transfer characteristics of a semiconductor device, as a function of voltage applied to a gate electrode and for different values of n-type doping concentration in the gallium nitride (GaN) regrown region, in accordance with an embodiment of the present disclosure. FIG. 7B is described in conjunction with elements from FIGS. 1, 2A, 2B, 2C, 3A, 3B, 4A, 4B, 6, and 7A. With reference to FIG. 7B, there is shown a graphical representation 700B that includes the X-axis 702 that illustrates gate voltage and the Y-axis 704 that illustrates current in amperes (A).

With reference to the graphical representation 700B, a first line 716, a second line 718, a third line 720, a fourth line 722, a fifth line 724, and a sixth line 726, collectively, illustrate the simulated electrical transfer characteristics of a semiconductor device (e.g., the FET 600), as a function of voltage applied to a gate electrode and for different values of the n-type doping concentration in the gallium nitride (GaN) regrown region (i.e., the source layer 104). As shown in the FIG. 7B, the semiconductor device (e.g., the FET 600) manifests a tunable threshold voltage approximately from 2 volts (V) to more than 6V. When the semiconductor device (e.g., the FET 600) is compared with a conventional p-GaN power MOSFETs that has a typical threshold voltage between 1V to 1.5V, it is evident that the semiconductor device (e.g., the FET 600) manifests an improved threshold voltage, that has a positive impact on the gate driver design and an overall system level performance.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the invention, which are, for brevity, described in the context of a single embodiment, may also be provided separately or in any suitable combination or as suitable in any other described embodiment of the disclosure.

1. A member comprising:
a buffer layer comprising GaN;
a source layer arranged on top of the buffer layer, the source layer comprising n-doped GaN;
a first barrier layer comprising Al—GaN arranged over the buffer layer; and
a first gate layer comprising p-doped GaN arranged over the first barrier layer;
a second barrier layer comprising Al—GaN arranged over the buffer layer;
a second gate layer comprising p-doped GaN arranged over the second barrier layer,
wherein the first barrier layer and the first gate layer are arranged adjacent the source layer on one side, and
wherein the second barrier layer and the second gate layer are arranged adjacent the source layer on a second side.

2. The member according to claim 1, wherein one or more drain contacts are arranged on at least one of the first and second barrier layers,
wherein one or more gate contacts are arranged on at least one of the first and second gate layers, and
wherein a source contact is arranged on the source layer.

3. The member according to claim 1, wherein the source layer is arranged in a hole in the first and second barrier layers and the first and second gate layers,
wherein the source layer is sandwiched between the first and second barrier layers and the first and second gate layers.

4. The member according to claim 3, wherein the hole is formed in an original barrier layer and an original gate layer, the first and second barrier layers and the first and second gate layers, and
wherein the source layer is a regrown body of n-doped GaN in the hole.

5. The member according claim 1, wherein the member comprises:
a first portion arranged, in operation, to provide current flow therethrough in a vertical direction, and
a second portion arranged, in operation, to provide current flow therethrough it in a lateral direction, and
wherein a threshold voltage of the member is dependent on the first portion.

6. The member according to claim 5, wherein the first portion comprises the source layer and a portion of the first gate layer, and
wherein the second portion comprises the remainder of the first gate layer and the first barrier layer.

7. The member according to claim 6, wherein the first portion further comprises a portion of the second gate layer, and
wherein the second portion further comprises the remainder of the second gate layer and the second barrier layer.

8. The member according to claim 1, wherein the source layer has a first length in a first lateral direction and a length in a second lateral direction,
wherein each of the first and second gate layers has a first length in a first lateral direction and a length in a second lateral direction, the lengths of either gate layer being measured from the source layer, and
wherein each of the first and second barrier layers has a first length in a first lateral direction and a length in a second lateral direction, the lengths of either barrier layer being measured from the source layer, and
wherein the first lateral direction is orthogonal to the second lateral direction.

9. The member according to claim 8, wherein the first length of the source layer in the first lateral direction is in a range of 0.2 μm to 5 μm.

10. The member according to claim 8, wherein the length of the source layer in the second lateral direction is in a range of 0.2 μm to 5 μm.

11. The member according to claim 8, wherein the first length of either gate layer in the first lateral direction is in a range of 0.2 μm to 5 μm.

12. The member according to claim 11, wherein at least one of the gate layers has a second length in the first lateral direction measured from the source layer, the second length in the first lateral direction being in a range of 0.2 μm to 5 μm.

13. The member according to claim 8, wherein the length of either gate layer in the second lateral direction is in a range of 0.2 μm to 5 μm.

14. The member according to claim 8, wherein the first length of either barrier layer in the first lateral direction is in a range of 1 μm to 20 μm.

15. The member according to claim 14, wherein at least one of the barrier layers has a second length in the first lateral direction measured from the source layer, the second length in the first lateral direction being in a range of 1 μm to 20 μm.

16. The member according to claim 8, wherein a length of either barrier layer in the second lateral direction is in a range of 1 μm to 20 μm.

17. The member according to claim 8, wherein a height of the source layer is in a range of 0.1 μm to 5 μm.

18. The member according to claim 8, wherein a height of either gate layer is in a range of 0.1 μm to 5 μm.

19. The member according to claim 8, wherein a concentration of the source layer is in a range of 1e16 cm⁻³ up to 5e18 cm⁻³.

20. The member according to claim 8, wherein a concentration of either gate layer is in a range of 1e18 cm⁻³ up to 5e19 cm⁻³.

21. The member according to claim 8, wherein a concentration of aluminium in either barrier layer is in a range of 15% to 30%.

22. The member according to claim 1, wherein the member further comprises a second source layer.

23. The member according to claim 1, further comprising:
one or more further first barrier layers;
one or more first intermediate buffer layers arranged between the first barrier layer and the buffer layer;
one or more further second barrier layers; and
one or more second intermediate buffer layers arranged between the second barrier layer and the buffer layer,
wherein the one or more further barrier layers comprise AlGaN, and
wherein the one or more intermediate buffer layers comprise GaN.

24. A method of manufacturing a member, the method comprising:
depositing a sacrificial layer on top of an epitaxial stack, the sacrificial layer indicating a location for a hole, the epitaxial stack comprising:
a buffer layer comprising GaN,
a barrier layer comprising Al—GaN arranged over the buffer layer, and
a gate layer comprising p-doped GaN arranged over the barrier layer;
etching the hole through the gate layer and the barrier layer as indicated by the sacrificial layer;
regrowing a source layer comprising n-doped GaN in the hole;
removing the sacrificial layer;
structuring the gate layer to expose a portion of the barrier layer;
depositing a passivation layer over the exposed portion of the barrier layer, the gate layer and the source layer;
arranging one or more drain contacts on the barrier layer;
arranging one or more gate contacts on the gate layer; and
arranging a source contact on the source layer.

25. The method according to claim 24, wherein the member comprises:
the buffer layer comprising GaN;
the source layer arranged on top of the buffer layer, the source layer comprising the n-doped GaN;
the barrier layer comprising Al—GaN arranged over the buffer layer;
the gate layer comprising p-doped GaN arranged over the barrier layer;
a second barrier layer comprising Al—GaN arranged over the buffer layer;
a second gate layer comprising p-doped GaN arranged over the second barrier layer,
wherein the barrier layer and the gate layer are arranged adjacent the source layer on one side, and
wherein the second barrier layer and the second gate layer are arranged adjacent the source layer on a second side.

26. A field effect transistor (FET) comprising:
a source contact;
one or more gate contacts;
one or more drain contacts,
a junction FET (JFET) arranged to provide the source contact; and
a first heterostructure FET and a second heterostructure FET, wherein the first and the second heterostructure FETs are arranged to provide the one or more gate contacts and the one or more drain contacts.

27. The FET according to claim 26, wherein the first and the second heterostructure FETs are arranged to provide each a gate and a drain of the one or more gate contacts and the one or more drain contacts.

28. The FET according to claim 26, wherein the first and the second heterostructure FETs are pGaN heterostructure FETs.

29. The FET according to claim 26, wherein the first and the second heterostructure FETs are formed as one structure enveloping the JFET.

30. The FET according to claim 26, wherein the FET provides for a threshold voltage in the range of 2 to 6 V.

31. The FET according to claim 26, wherein the FET comprises a member comprising
a buffer layer comprising GaN;
a source layer arranged on top of the buffer layer, the source layer comprising n-doped GaN;
a first barrier layer comprising Al—GaN arranged over the buffer layer;
a first gate layer comprising p-doped GaN arranged over the first barrier layer;
a second barrier layer comprising Al—GaN arranged over the buffer layer;
a second gate layer comprising p-doped GaN arranged over the second barrier layer,
wherein the first barrier layer and the first gate layer are arranged adjacent the source layer on one side, and
wherein the second barrier layer and the second gate layer are arranged adjacent the source layer on a second side.
